(19) United States
(12) Patent Application Publication
(10) Pub. No.: US 2025/0125573 A1
(43) Pub. Date: Apr. 17, 2025

(54) OPTICAL FILTER AND WAVELENGTH TUNABLE LASER ELEMENT

(71) Applicants: SUMITOMO ELECTRIC INDUSTRIES, LTD., Osaka-shi (JP); NATIONAL UNIVERSITY CORPORATION HOKKAIDO UNIVERSITY, Sapporo-shi (JP)

(72) Inventors: Takuo HIRATANI, Osaka-shi (JP); Kunimasa SAITOH, Sapporo-shi (JP); Takanori SATO, Sapporo-shi (JP)

(73) Assignees: SUMITOMO ELECTRIC INDUSTRIES, LTD, Osaka-shi (JP); NATIONAL UNIVERSITY CORPORATION HOKKAIDO UNIVERSITY, Sapporo-shi (JP)

(21) Appl. No.: 18/915,530

(22) Filed: Oct. 15, 2024

(30) Foreign Application Priority Data
Oct. 16, 2023 (JP) 2023-178439

(51) Int. Cl. H01S 3/083; G02B 6/293; H01S 3/00

(52) U.S. Cl. CPC H01S 3/083; G02B 6/2934; G02B 6/2938; H01S 3/0078

(57) ABSTRACT

An optical filter includes a first multiplexer having a first input end, a second input end, a first output end, and a second output end, a first waveguide optically coupled to the first input end, a second waveguide optically coupled to the second input end, a third waveguide optically coupled to the first output end, a fourth waveguide optically coupled to the second output end, and a ring resonator optically coupled to the third waveguide and the fourth waveguide.

### CROSS REFERENCE TO RELATED APPLICATIONS

This application claims priority based on Japanese Patent Application No. 2023-178439 filed on Oct. 16, 2023, and the entire contents of the Japanese patent application are incorporated herein by reference.

### TECHNICAL FIELD

The present disclosure relates to an optical filter and a wavelength tunable laser element.

### BACKGROUND OF THE INVENTION

An optical filter using silicon photonics is known. An optical filter has been developed in which a resonator is formed by a plurality of waveguides and light having a specific wavelength is excited (for example, patent literature 1: Japanese Unexamined Patent Application Publication No. 2022-84531).

### SUMMARY OF THE INVENTION

An optical filter according to the present disclosure includes a first multiplexer having a first input end, a second input end, a first output end, and a second output end; a first waveguide optically coupled to the first input end; a second waveguide optically coupled to the second input end; a third waveguide optically coupled to the first output end; a fourth waveguide optically coupled to the second output end; and a ring resonator optically coupled to the third waveguide and the fourth waveguide.

### BRIEF DESCRIPTION OF THE DRAWINGS

FIG. 1 is a plan view illustrating an optical filter according to a first embodiment.

FIG. 2 is a cross-sectional view illustrating the optical filter.

FIG. 3 is a diagram illustrating the propagation of light in the optical filter.

FIG. 4 is a diagram illustrating the propagation of light in the optical filter.

FIG. 5A is a diagram illustrating a spectrum of reflection light.

FIG. 5B is a diagram illustrating a spectrum of transmitted light.

FIG. 6 is a plan view illustrating an optical filter according to a comparative example.

FIG. 7A is a diagram illustrating calculation results of light intensity.

FIG. 7B is a diagram illustrating the calculation results of light intensity.

FIG. 8 is a plan view illustrating an optical filter according to a second embodiment.

FIG. 9 is a diagram illustrating the propagation of light in the optical filter.

FIG. 10 is a diagram illustrating the propagation of light in the optical filter.

FIG. 11 is a plan view illustrating a wavelength tunable laser element according to a third embodiment.

### DETAILED DESCRIPTION

In an optical filter, light is split into waveguides by a multiplexer. By setting the splitting ratio of light in the multiplexer to a specific value, it is possible to control the port through which light propagates. For example, light is emitted from a certain port, and light is not emitted from another port. However, the splitting ratio may deviate from the designed value. The influence of the deviation of the splitting ratio increases when the light passes through the multiplexer multiple times. As a result, crosstalk between ports increases. Thus, the purpose of the present invention is to provide an optical filter and a wavelength tunable laser element capable of suppressing crosstalk.

### Description of Embodiments of Present Disclosure

First, the contents of embodiments of the present disclosure will be listed and explained.

(1) One aspect of the present disclosure is an optical filter includes a first multiplexer having a first input end, a second input end, a first output end, and a second output end; a first waveguide optically coupled to the first input end; a second waveguide optically coupled to the second input end, a third waveguide optically coupled to the first output end; a fourth waveguide optically coupled to the second output end; and a ring resonator optically coupled to the third waveguide and the fourth waveguide. Crosstalk can be suppressed by reducing the number of times light passes through the first multiplexer.

(2) In (1), the optical filter may include a second multiplexer having a third input end, a fourth input end, a third output end, and a fourth output end; a fifth waveguide optically coupled to the third output end; and a sixth waveguide optically coupled to the fourth output end. The third waveguide may be optically coupled to the third input end. The fourth waveguide may be optically coupled to the fourth input end. Crosstalk can be suppressed by reducing the number of times light passes through the first multiplexer and the second multiplexer.
(3) In (2), an optical path length of the third waveguide from the first output end to a coupling portion in which the third waveguide and the ring resonator are coupled to each other may be equal to an optical path length of the fourth waveguide from the second output end to a coupling portion in which the fourth waveguide and the ring resonator are coupled to each other. An optical path length of the third waveguide from the coupling portion in which the third waveguide and the ring resonator are coupled to each other to the third input end may be equal to an optical path length of the fourth waveguide from the coupling portion in which the fourth waveguide and the ring resonator are coupled to each other to the fourth input end. The phase shift of light can be suppressed, and crosstalk can be suppressed.
(4) In (2) or (3), the ring resonator, the first waveguide, the second waveguide, the third waveguide, the fourth waveguide, the fifth waveguide, and the sixth waveguide may be each made of silicon. The loss of light can be suppressed.
(5) In (1), the optical filter may include a third multiplexer having a fifth input end, a sixth input end, a fifth output end, and a sixth output end; a seventh waveguide optically coupled to the fifth input end, the ring resonator, and the sixth input end; an eighth waveguide optically coupled to the fifth output end; and a ninth waveguide optically coupled to the sixth output end. Crosstalk can be suppressed by reducing the number of times light passes through the first multiplexer and the third multiplexer. The resonated light can be output.
(6) In (5), a first end portion of the seventh waveguide may be optically coupled to the fifth input end, and a second end portion of the seventh waveguide may be optically coupled to the sixth input end. The seventh waveguide may be coupled to the ring resonator between the first end portion and the second end portion. The resonated light can be propagated to the eighth waveguide and the ninth waveguide.
(7) In (5) or (6), an optical path length of the third waveguide from the first output end to a coupling portion in which the third waveguide and the ring resonator are coupled to each other may be equal to an optical path length of the fourth waveguide from the second output end to a coupling portion in which the fourth waveguide and the ring resonator are coupled to each other. An optical path length of the seventh waveguide from a coupling portion in which the ring resonator and the seventh waveguide are coupled to each other to the fifth input end may be equal to an optical path length of the seventh waveguide from the coupling portion in which the ring resonator and the seventh waveguide are coupled to each other to the sixth input end. The phase shift of light can be suppressed, and crosstalk can be suppressed.
(8) In any one of (5) to (7), the ring resonator, the first waveguide, the second waveguide, the third waveguide, the fourth waveguide, the seventh waveguide, the eighth waveguide, and the ninth waveguide may be each made of silicon. The loss of light can be suppressed.
(9) A wavelength tunable laser element includes a light source and two optical filters. Each of the two optical filters includes a first multiplexer having a first input end, a second input end, a first output end, a second output end; a first waveguide optically coupled to the first input end; a second waveguide optically coupled to the second input end; a third waveguide optically coupled to the first output end; a fourth waveguide optically coupled to the second output end; a ring resonator optically coupled to the third waveguide and the fourth waveguide; a third multiplexer having a fifth input end, a sixth input end, a fifth output end, a sixth output end; a seventh waveguide optically coupled to the fifth input end, the ring resonator, the sixth input end; an eighth waveguide optically coupled to the fifth output end; and a ninth waveguide optically coupled to the sixth output end. The light source is optically coupled to the first waveguides of the two optical filters. Crosstalk is suppressed by the two optical filters. Light is reflected by the two optical filters, and laser oscillation occurs. The optical filter can be monitored by the light emitted from the optical filter.
(10) In (9), circumferential lengths of the ring resonators of the two optical filters may be different from each other. The resonance wavelengths of the two optical filters are matched, and the light is laser-oscillated.
(11) In (9) or (10), the wavelength tunable laser element may include phase adjusting units each included in a corresponding one of the two optical filters and each configured to adjust a phase of light propagating through the corresponding optical filter. The laser light can be controlled by adjusting the phase of the light.

### Details of Embodiments of Present Disclosure

Specific examples of an optical filter and a wavelength tunable laser element according to embodiments of the present disclosure will be described below with reference to the drawings. It is noted that the present disclosure is not limited to these examples, but is defined by the scope of the claims, and is intended to include all modifications within the meaning and scope equivalent to the scope of the claims.

### First Embodiment

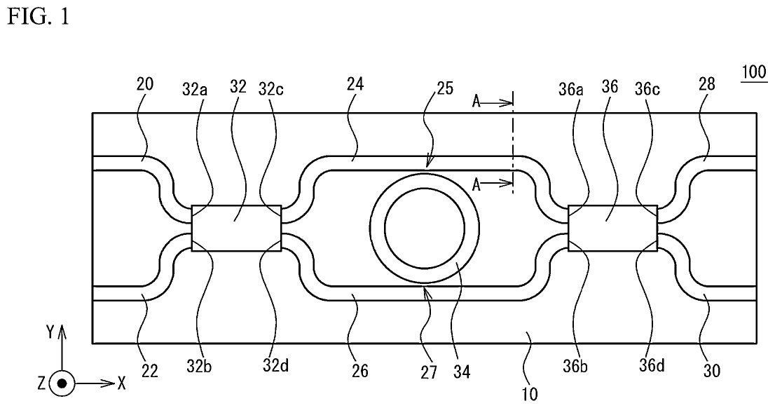

FIG. 1 is a plan view illustrating an optical filter 100 according to a first embodiment. As illustrated in FIG. 1, optical filter 100 is formed on a substrate 10. Two sides of substrate 10 are parallel to the X-axis. The other two sides are parallel to the Y-axis. The Z-axis is a normal direction of the upper surface of substrate 10. The X-axis, the Y-axis, and the Z-axis are orthogonal to each other.

Optical filter 100 includes a waveguide 20 (first waveguide), a waveguide 22 (second waveguide), a multiplexer 32 (first multiplexer), a waveguide 24 (third waveguide), a waveguide 26 (fourth waveguide), a ring resonator 34, a multiplexer 36 (second multiplexer), a waveguide 28 (fifth waveguide), and a waveguide 30 (sixth waveguide).

Multiplexer 32 and multiplexer 36 are 3 dB couplers, for example, a two-input two-output MMI (Multi Mode Interfere). Multiplexer 32 includes an input end 32a (first input end), an input end 32b (second input end), an output end 32c (first output end), and an output end 32d (second output end). Multiplexer 36 includes an input end 36a (third input end), an input end 36b (fourth input end), an output end 36c (third output end), and an output end 36d (fourth output end).

One end portion of waveguide 20 and one end portion of waveguide 22 are located at one end portion of substrate 10 in the X-axis direction. The other end portion of waveguide 20 is optically coupled to input end 32a of multiplexer 32. The other end portion of waveguide 22 is optically coupled to input end 32b of multiplexer 32.

One end portion of waveguide 24 is optically coupled to output end 32c of multiplexer 32. The other end portion of waveguide 24 is optically coupled to input end 36a of multiplexer 36. One end portion of waveguide 26 is optically coupled to output end 32d of multiplexer 32. The other end portion of waveguide 26 is optically coupled to input end 36b of multiplexer 36.

One end portion of waveguide 28 is optically coupled to output end 36c of multiplexer 36. One end portion of waveguide 30 is optically coupled to output end 36d of multiplexer 36. The other end portion of waveguide 28 and the other end portion of waveguide 30 are located at the other end portion of substrate 10 in the X-axis direction.

Ring resonator 34 is a loop-type waveguide. The planar shape of ring resonator 34 is a circle, ellipse, polygon, or the like. Ring resonator 34 is located between multiplexer 32 and multiplexer 36. Multiplexer 32, ring resonator 34, and multiplexer 36 are arranged in this order in the X-axis direction. Waveguide 24, ring resonator 34, and waveguide 26 are arranged in this order in the Y-axis direction.

A directional coupler 25 is formed at a position where waveguide 24 is closest to ring resonator 34. In directional coupler 25, waveguide 24 is optically coupled to ring resonator 34. A directional coupler 27 is formed at a position where waveguide 26 is closest to ring resonator 34. In directional coupler 27, waveguide 26 is optically coupled to ring resonator 34.

The optical path length of waveguide 20 is equal to the optical path length of waveguide 22. The optical path length from output end 32c to directional coupler 25 is equal to the optical path length from output end 32d to directional coupler 27. The optical path length from directional coupler 25 to input end 36a is equal to the optical path length from directional coupler 27 to input end 36b. The optical path length of waveguide 28 is equal to the optical path length of waveguide 30.

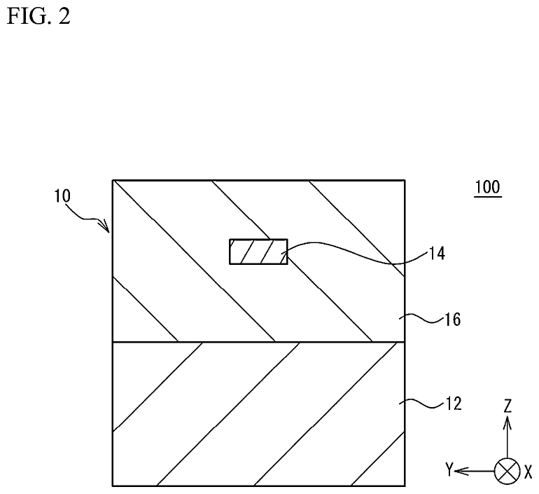

FIG. 2 is a cross-sectional view illustrating optical filter 100 and illustrates a cross-section along line A-A of FIG. 1. Substrate 10 is an SOI (silicon on insulator) substrate, and includes a substrate 12, a cladding layer 16, and a waveguide core 14. Substrate 10 is formed of, for example, silicon (Si). Cladding layer 16 is formed of, for example, silicon oxide (SiO₂), and covers one surface of substrate 10. Waveguide core 14 is formed of, for example, Si, and is spaced apart from substrate 10 and embedded in cladding layer 16. Waveguide core 14 functions as waveguide 24. The distance from the upper surface of substrate 12 to the lower end of waveguide core 14 is, for example, 2 μm. The width of waveguide core 14 in the Y-axis direction is, for example, 440 nm. The thickness of waveguide core 14 is, for example, 220 nm.

The cross sections of waveguide 20, waveguide 22, waveguide 26, waveguide 28, waveguide 30, and ring resonator 34 are the same as the cross section in FIG. 2.

The operation of optical filter 100 will be described. The end portion of waveguide 20 and the end portion of waveguide 22 function as an input port and an output port. The end portion of waveguide 28 and the end portion of waveguide 30 function as output ports. Optical filter 100 transmits two independent resonance modes.

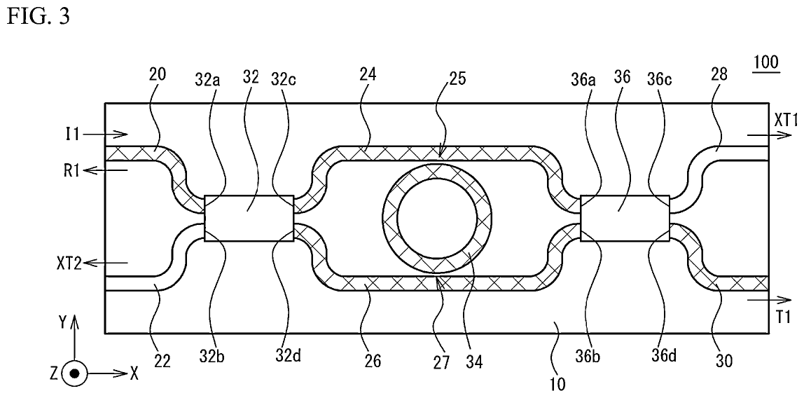

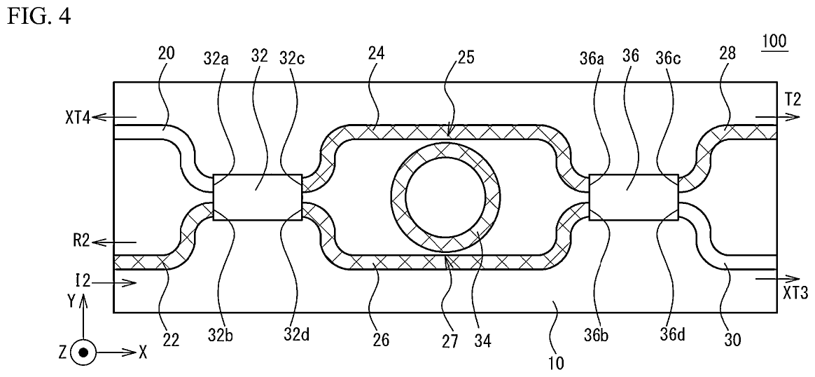

FIG. 3 and FIG. 4 are diagrams illustrating the propagation of light in optical filter 100. The portion where light propagates is indicated by diagonal lines.

In the example of FIG. 3, light I1 is incident on waveguide 20 from an external light source. No light is incident on other waveguides from the external light source. The light propagates through waveguide 20 and inputs to input end 32a of multiplexer 32. Multiplexer 32 demultiplexes the light into output end 32c and output end 32d. Ideally, the ratio of the intensity of the light to be split is 50:50. The phase of the light output from output end 32d to waveguide 26 is delayed by 90° compared to the light output from output end 32c to waveguide 24.

The light propagating through waveguide 24 is transferred to ring resonator 34 and propagates clockwise through ring resonator 34. The light propagating through waveguide 26 is transferred to ring resonator 34 and propagates counterclockwise through ring resonator 34.

The light circulates around ring resonator 34 multiple times and resonates. The resonance wavelength is determined in accordance with the circumferential length of ring resonator 34. The light resonated in ring resonator 34 is reflected as reflection light, transferred from ring resonator 34 to waveguide 24 or waveguide 26, and propagated toward multiplexer 32.

The reflection light propagating through waveguide 24 inputs to output end 32c of multiplexer 32. Multiplexer 32 demultiplexes the reflection light input from waveguide 24 into input end 32a and input end 32b. The reflection light propagating through waveguide 26 inputs to output end 32d. Multiplexer 32 demultiplexes the reflection light input from waveguide 26 into input end 32a and input end 32b. The splitting ratio of the reflection light is ideally 50:50.

The phase of the reflection light input to input end 32b, propagating through waveguide 24, is different by 180° from the phase of the reflection light input to input end 32b, propagating through waveguide 26. Since the phases are inverted from each other, the two reflection lights cancel out each other.

The phase of the reflection light input to input end 32a, propagating through waveguide 24, is equal to the phase of the reflection light input to input end 32a, propagating through waveguide 26. The two reflection lights strengthen each other. Reflection light R1 propagates through waveguide 20 and is emitted from the end portion of waveguide 20.

The transmitted light propagating through waveguide 24 inputs to input end 36a of multiplexer 36. Multiplexer 36 demultiplexes the transmitted light input from waveguide 24 into output end 36c and output end 36d. The transmitted light propagating through waveguide 26 inputs to input end 36b. Multiplexer 36 demultiplexes the transmitted light input from waveguide 26 into output end 36c and output end 36d. The splitting ratio is ideally 50:50.

The phase of the transmitted light input to output end 36c, propagating through waveguide 24, is different by 180° from the phase of the transmitted light input to output end 36c, propagating through waveguide 26. Since the phases are inverted from each other, the two transmitted lights cancel out each other.

The phase of the transmitted light input to output end 36d, propagating through waveguide 24, is equal to the phase of the transmitted light input to output end 36d, propagating through waveguide 26. The two transmitted lights strengthen each other. Transmitted light T1 propagates through waveguide 30 and is emitted from the end portion of waveguide 30.

XT1 in FIG. 3 represents light leaking into waveguide 28. XT2 represents light leaking into waveguide 22. The light that leaks as light XT1 and XT2 may be referred to as crosstalk. Ideally, the intensity of light XT1 and XT2 is zero.

In the example of FIG. 4, light I2 is incident on waveguide 22 from an external light source. No light is incident on other waveguides from the external light source. The light propagates through waveguide 22 and inputs to input end 32b of multiplexer 32.

Multiplexer 32 demultiplexes the light into output end 32c and output end 32d. The light resonated in ring resonator 34 is reflected as reflection light, transferred from ring resonator 34 to waveguide 24 or waveguide 26, and propagated toward multiplexer 32. Reflection light R2 is emitted from the end portion of waveguide 22. Transmitted light T2 is emitted from the end portion of waveguide 28. XT3 in FIG. 4 represents light leaking into waveguide 30. XT4 represents light leaking to waveguide 20. Ideally, the intensity of light XT3 and XT4 is zero.

When light is incident on both waveguide 20 and waveguide 22, two independent resonance modes are excited. As in the example of FIG. 3, reflection light R1 is emitted from waveguide 20 and transmitted light T1 is emitted from waveguide 30. As in the example of FIG. 4, reflection light R2 is emitted from waveguide 22, and transmitted light T2 is emitted from waveguide 28.

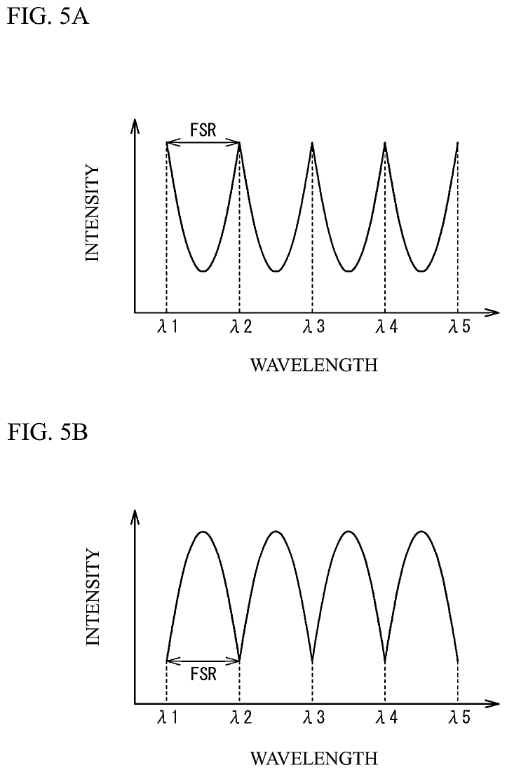

FIG. 5A is a diagram illustrating a spectrum of reflection light. The horizontal axis represents the wavelength of light. The vertical axis represents the intensity of light. The spectrum of the reflection light has peaks at resonance wavelengths λ1, λ2, λ3, λ4, and λ5. In the peak, the intensity indicates the local maximum value. The interval between two adjacent resonance wavelengths is a free spectral range (FSR).

FIG. 5B is a diagram illustrating the spectrum of transmitted light. The horizontal axis represents the wavelength of light. The vertical axis represents the intensity of light. The transmitted light is quenched at the resonance wavelengths λ1, λ2, λ3, λ4 and λ5. That is, the intensity becomes the local minimum value.

Two reflection lights R1 and R2 have the same wavelength characteristics. The FSR of reflection light R1 and the FSR of reflection light R2 are matched in principle. For example, when one reflection light R1 shows a peak, the other reflection light R2 also shows a peak. By measuring one of the two reflection lights, it is possible to monitor the characteristics of optical filter 100 such as the resonance wavelength and the FSR.

Two transmitted lights T1 and T2 have the same wavelength characteristics. The FSR of the two transmitted lights is matched in principle. For example, when the wavelength of the light is the resonance wavelength, when one transmitted light T1 is quenched, the other transmitted light T2 is also quenched. The reflection light indicates a peak. By measuring the transmitted light, the characteristics of optical filter 100 can be monitored.

### Comparative Example

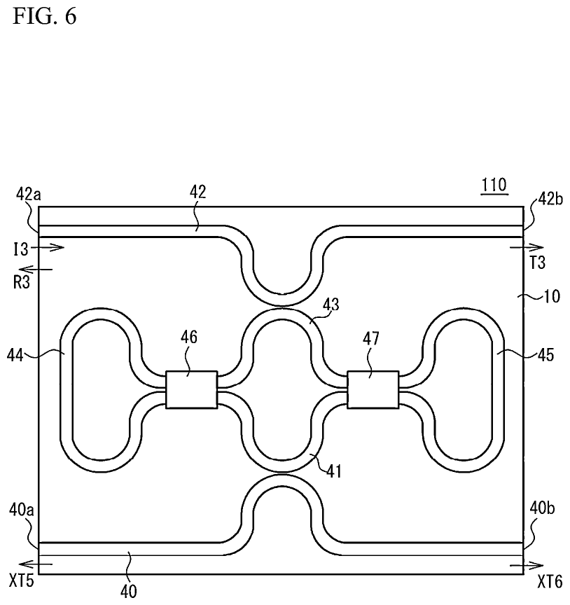

FIG. 6 is a plan view illustrating an optical filter 110 according to a comparative example. Optical filter 110 includes a waveguide 40, a waveguide 41, a waveguide 42, a waveguide 43, a waveguide 44, a waveguide 45, a multiplexer 46, and a multiplexer 47.

Waveguide 40 and waveguide 42 are access waveguides for inputting and outputting light, and extend from one end portion to the other end portion of substrate 10. Waveguide 40 and waveguide 41 are close to each other, for example, to about several hundred nm, and are optically coupled. Waveguide 42 and waveguide 43 are optically coupled.

Multiplexer 46 and multiplexer 47 are two-input two-output couplers. One end of each of waveguide 41 and waveguide 43 is optically coupled to an input end of multiplexer 46. The other end of each of waveguide 41 and waveguide 43 is optically coupled to the input end of multiplexer 47.

Waveguide 44 and waveguide 45 have a loop shape. Both ends of waveguide 44 are coupled to the output ends of multiplexer 46. Both ends of waveguide 45 are coupled to the output ends of multiplexer 47.

When light I3 is incident from an end portion 42a of waveguide 42, the light is transferred from waveguide 42 to waveguide 43. The light propagating through waveguide 43 is distributed to both ends of waveguide 44 by multiplexer 46, and is distributed to both ends of waveguide 45 by multiplexer 47. Waveguide 43, waveguide 44, waveguide 45, multiplexer 46, and multiplexer 47 function as resonators. The light propagates repeatedly through waveguide 43, waveguide 44, waveguide 45, multiplexer 46, and multiplexer 47, and resonates at a wavelength determined by the optical path length. The resonated light R3 is transferred from waveguide 43 to waveguide 42 and is emitted from end portion 42a. Transmitted light T3 is emitted from other end portion 42b of waveguide 42.

Ideally, light does not propagate in waveguide 41 and waveguide 40. However, the leaked light XT5 may propagate toward an end portion 40a of waveguide 40, and the leaked light XT6 may propagate toward an end portion 40b of waveguide 40.

The crosstalk depends on the splitting ratio of light in the multiplexer. When an error occurs in the splitting ratio, crosstalk increases.

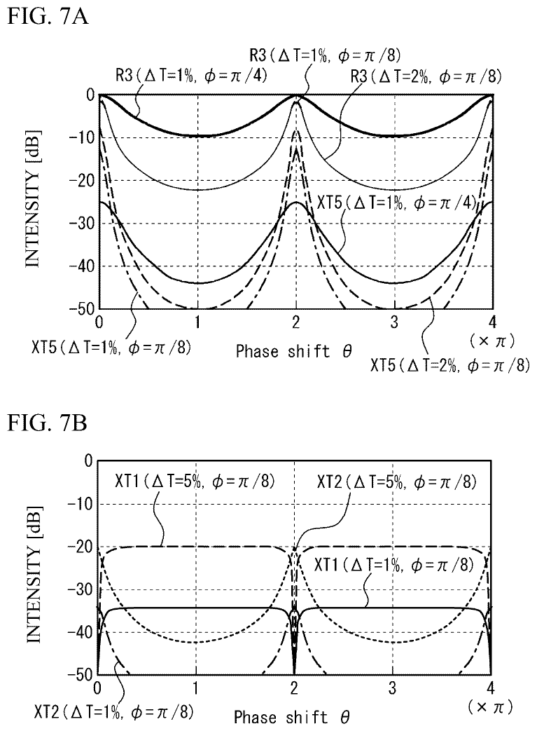

FIG. 7A and FIG. 7B are diagrams illustrating the calculation results of light intensity. The horizontal axis represents the phase of light in the resonator, and θ=2nπ is the resonance condition (n is an integer). The vertical axis represents the intensity of light.

ΔT represents a deviation of the splitting ratio in the multiplexer. An ideal splitting ratio is 50:50. The splitting ratio in the example of FIG. 7A and FIG. 7B is (50+ΔT):(50−ΔT). The power coupling coefficient between the resonator and the waveguide is represented by sin φ².

FIG. 7A illustrates the calculation results in the comparative example. A thick solid line represents reflection light R3 (ΔT=1%, φ=π/4). The thin solid line represents crosstalk XT5 (ΔT=1%, φ=π/4). The dotted line represents reflection light R3 (ΔT=1%, φ=π/8). The one dot chain line represents crosstalk XT5 (ΔT=1%, φ=π/8). The two dot chain line represents reflection light R3 (ΔT=2%, φ=π/8). The dashed line represents crosstalk XT5 (ΔT=2%, φ=π/8). Although the results of crosstalk XT6 is not illustrated, the results of crosstalk XT6 are similar to those of crosstalk XT5.

Reflection light R3 shows high intensity in the resonance condition 2nπ. Crosstalk XT5 depends on ΔT and φ. The higher ΔT is, the larger the maximum value of crosstalk XT5 becomes. In the comparative example, the light passes through multiplexer 46 and multiplexer 47 repeatedly. Since the influence of the deviation ΔT of the splitting ratio in the multiplexer is accumulated, crosstalk XT5 increases. When ΔT is the same, crosstalk XT5 increases as φ decreases. When φ is small, the Q value of the resonator increases. A small value of φ has the same effect on crosstalk as an increase in the number of times light circulates around the resonator.

FIG. 7B illustrates the calculation results in the first embodiment. The solid line represents crosstalk XT1 (ΔT=1%, φ=π/8). The one dot chain line represents crosstalk XT2 (ΔT=1%, φ=π/8). The dashed line represents crosstalk XT1 (ΔT=5%, φ=π/8). The dotted line represents crosstalk XT2 (ΔT=5%, φ=π/8). In the examples (solid line and one dot chain line) of ΔT=1%, the crosstalk is about-34 dB at most, and is suppressed to be lower than the crosstalk of ΔT=1% in the comparative example. In the example of ΔT=5% (dashed line and dotted line), the crosstalk is at most about −20 dB.

According to the first embodiment, waveguide 20 is optically coupled to input end 32a of multiplexer 32. Waveguide 22 is optically coupled to input end 32b. Waveguide 24 is optically coupled to output end 32c. Waveguide 26 is optically coupled to output end 32d. Ring resonator 34 is optically coupled to waveguide 24 and waveguide 26. The light resonates in ring resonator 34 and is reflected. When light is incident on waveguide 20, reflection light R1 propagates through waveguide 20. When light is incident on waveguide 22, reflection light R2 propagates through waveguide 22.

The splitting ratio of light in multiplexer 32 is designed to be, for example, 50:50. The splitting ratio may deviate from the designed value due to a fabrication error or the like. The number of times the light passes through multiplexer 32 from the time the light is incident on optical filter 100 to the time the reflection light is emitted is two. Since the number of times of passing through multiplexer 32 is reduced, the light is hardly affected by the deviation of the splitting ratio. Thus, it is possible to suppress crosstalk. As in the example of FIG. 7B, when the deviation of the splitting is ΔT=1% and ΔT=5%, crosstalks XT1 and XT2 can be reduced as compared with the comparative example.

Since the crosstalk is suppressed, two reflection lights can be separated and extracted. The two reflection lights can be used for different purposes. For example, one reflection light is used for laser oscillation. The other reflection light can be used to monitor the characteristics of optical filter 100, such as the resonance wavelength and the FSR.

When a resonator is formed by a plurality of waveguides, the resonator length becomes long, and therefore it is difficult to increase the FSR. According to the first embodiment, optical filter 100 includes one ring resonator 34. The FSR can be increased by shortening the circumferential length of ring resonator 34. For example, the circumferential length may be 100 μm to 300 μm, 100 μm or less, or 600 μm or less. When the circumferential length is 100 μm or more and about 600 μm, the FSR is 1 nm to 6 nm.

Waveguide 24 is optically coupled to input end 36a of multiplexer 36. Waveguide 26 is optically coupled to input end 36b. Waveguide 28 is optically coupled to output end 36c. Waveguide 30 is optically coupled to output end 36d. When light is incident on waveguide 20, transmitted light T1 propagates through waveguide 30. When light is incident on waveguide 22, transmitted light T2 propagates through waveguide 28. The number of times the light passes through the multiplexer from the time the light is incident on optical filter 100 to the time the transmitted light is emitted is two. Since the number of times of passing through the multiplexer is limited, the light is hardly affected by the deviation of the splitting ratio. Thus, it is possible to suppress crosstalk. The two transmitted lights can be separated and extracted. The characteristics of optical filter 100 may be monitored using the transmitted light.

The optical path length of waveguide 24 from output end 32c to directional coupler 25 is equal to the optical path length of waveguide 26 from output end 32d to directional coupler 27. The optical path length of waveguide 24 from directional coupler 25 to input end 36a is equal to the optical path length of waveguide 26 from directional coupler 27 to input end 36b. The phase of the light propagating through waveguide 24 is less likely to be shifted from the phase of the light propagating through waveguide 26. The optical path lengths may be exactly equal, or may be equal within a range of, for example, a fabrication error.

By suppressing the influence of the splitting ratio deviation and suppressing the phase deviation, in principle, the reflection light is canceled out and does not propagate to waveguide 22 as in the example of FIG. 3. The transmitted light is cancelled out and does not propagate to waveguide 28. As in the example of FIG. 4, the reflection light is cancelled out and does not propagate to waveguide 20. The transmitted light is cancelled out and does not propagate to waveguide 30. Crosstalk is suppressed and the two resonance modes are excited independently. Reflection light R1 and reflection light R2 can be separated and extracted. Transmitted light T1 and transmitted light T2 can be separated and extracted. These lights can be used for different purposes.

As illustrated in FIG. 2, the waveguide and ring resonator 34 are formed of waveguide core 14 of Si. Light is confined in the curved waveguide, and loss can be suppressed. Even when the bending radius of ring resonator 34 is reduced, the loss of light can be suppressed. The circumferential length is shortened, and the FSR can be increased.

Optical filter 100 may be formed on a component other than the SOI substrate. Multiplexer 32 and multiplexer 36 are two-input two-output couplers, and may be directional couplers or the like other than the MMI.

### Second Embodiment

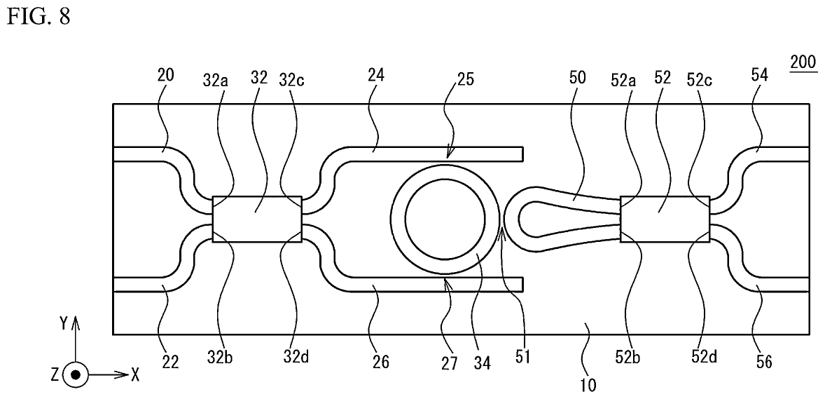

FIG. 8 is a plan view illustrating an optical filter 200 according to a second embodiment. The description of the same configuration as that of the first embodiment will be omitted.

Optical filter 200 includes waveguide 20, waveguide 22, multiplexer 32, waveguide 24, waveguide 26, ring resonator 34, a waveguide 50 (seventh waveguide), a multiplexer 52 (third multiplexer), a waveguide 54 (eighth waveguide), and a waveguide 56 (ninth waveguide).

Ring resonator 34 and waveguide 50 are provided between multiplexer 32 and multiplexer 52. Waveguide 54 and waveguide 56 are provided on the side of multiplexer 52 opposite to waveguide 50. Waveguide 24 and waveguide 26 are not coupled to multiplexer 52.

Multiplexer 52 includes an input end 52a (fifth input end), an input end 52b (sixth input end), an output end 52c (fifth output end), and an output end 52d (sixth output end).

Waveguide 50 is C-shaped and has both ends. Waveguide 50 is closest to ring resonator 34 in a portion between both ends, and forms a directional coupler 51. In directional coupler 51, waveguide 50 and ring resonator 34 are optically coupled. The coupling efficiency between waveguide 50 and ring resonator 34 is determined by the distance between waveguide 50 and ring resonator 34. The smaller the distance, the higher the coupling efficiency, and the greater the intensity of the light that transitions between ring resonator 34 and waveguide 50. The larger the distance, the lower the coupling efficiency and the lower the intensity of the light that is transferred.

One end portion of waveguide 50 is optically coupled to input end 52a of multiplexer 52. The other end portion of waveguide 50 is optically coupled to input end 52b. One end portion of waveguide 54 is optically coupled to output end 52c. One end portion of waveguide 56 is optically coupled to output end 52d. The other end portion of waveguide 54 and the other end portion of waveguide 56 are located at the end portion of substrate 10 and function as output ports.

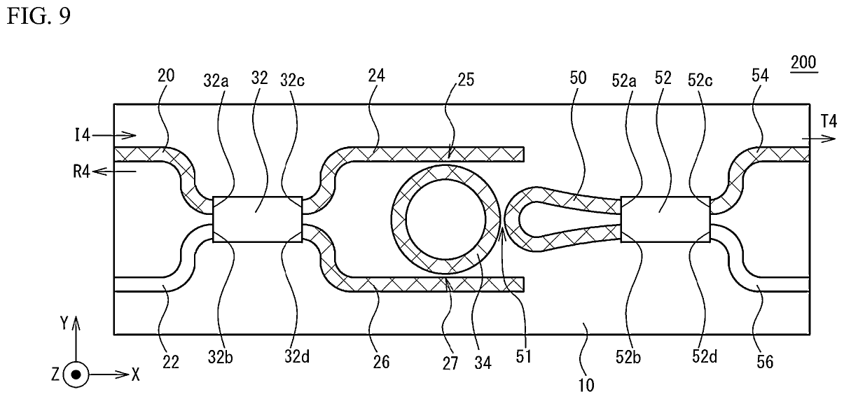

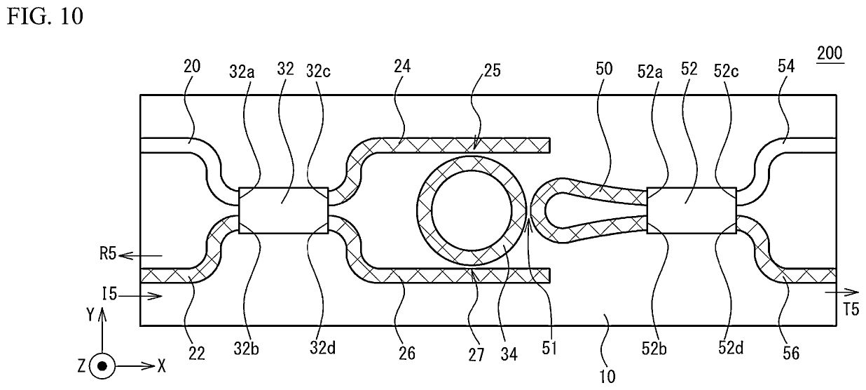

FIG. 9 and FIG. 10 are diagrams illustrating the propagation of light in optical filter 200. The portion where light propagates is indicated by diagonal lines. Optical filter 200 excites two independent resonance modes.

In the example of FIG. 9, light I4 is incident on waveguide 20 from an external light source. No light is incident on other waveguides from the external light source. The light propagates through waveguide 20 and inputs to input end 32a of multiplexer 32. Multiplexer 32 demultiplexes the light into output end 32c and output end 32d. The light propagating through waveguide 24 is transferred to ring resonator 34. The light propagating through waveguide 26 is transferred to ring resonator 34.

A portion of the light resonated in ring resonator 34 is transferred to waveguide 50 and inputs to input end 52a and input end 52b of multiplexer 52. Multiplexer 52 demultiplexes the light into output end 52c and output end 52d. Ideally, the splitting ratio is 50:50.

The phase of the light input from input end 52b and output to output end 52d is different by 180° from the phase of the light input from input end 52a and output to output end 52d. Since the phases are inverted from each other, the two lights cancel out each other. Ideally, no light propagates in waveguide 56.

The phase of the light input from input end 52a and output to output end 52c is equal to the phase of the light input from input end 52b and output to output end 52c. The two lights strengthen each other. Transmitted light T4 propagates through waveguide 54 and is emitted from the end portion of waveguide 54.

A portion of the resonated light is reflected from ring resonator 34 toward multiplexer 32. Reflection light R4 is emitted from waveguide 20.

In the example of FIG. 10, light I5 is incident on waveguide 22 from an external light source. No light is incident on other waveguides from the external light source. Transmitted light T5 is emitted from waveguide 56. Reflection light R5 is emitted from waveguide 22.

When light is incident on both waveguide 20 and waveguide 22, two independent resonance modes are excited. Transmitted light T4 is emitted from waveguide 54, and reflection light R4 is emitted from waveguide 20.

Transmitted light T5 is emitted from waveguide 56, and reflection light R5 is emitted from waveguide 22.

Transmitted light T4, transmitted light T5, reflection light R4 and reflection light R5 have the same wavelength characteristics, for example, the spectrum illustrated in FIG. 5A. That is, the transmitted light and the reflection light have peaks at the same resonance wavelength. By measuring one of the two transmitted lights, the characteristics of optical filter 200, such as the resonance wavelength and the FSR, can be monitored.

According to the second embodiment, waveguide 50 is optically coupled to ring resonator 34 and input end 52a and input end 52b of multiplexer 52. Waveguide 54 is optically coupled to output end 52c of multiplexer 52. Waveguide 56 is optically coupled to output end 52d. The light resonated by ring resonator 34 is transferred to waveguide 50 and is emitted from waveguide 54 and waveguide 56. The number of times the light passes through the multiplexer from the time the light is incident on optical filter 200 to the time the transmitted light is emitted is two. The number of times the light passes through the multiplexer until the reflection light is emitted is also two. Since the number of times of passing through the multiplexer is reduced, the light is hardly affected by the deviation of the splitting ratio. Thus, it is possible to suppress crosstalk.

Since the crosstalk is suppressed, waveguide 54 and waveguide 56 can be used as output waveguides to separate and extract the resonated light. Transmitted light T4 and transmitted light T5 have the same wavelength characteristics. By measuring one of the two transmitted lights, the characteristics of optical filter 200, such as the resonance wavelength and the FSR, can be monitored. For example, transmitted light T5 is used for monitoring, and the wavelength is set to the resonance wavelength. Transmitted light T4 having a peak at the resonance wavelength may be output. Reflection lights R4 and R5 also have the same wavelength characteristics as the transmitted light. The reflection light may be used for monitoring.

The FSR can be increased by shortening the circumferential length of ring resonator 34. For example, the circumferential length may be 100 μm to 300 μm, 100 μm or less, or 600 μm or less.

One end portion of waveguide 50 is coupled to input end 52a, and the other end portion is coupled to input end 52b. The resonated light propagates through waveguide 50 and is input to multiplexer 52 from the two end portions. The resonated light can be propagated in waveguides 54 and 56 coupled to multiplexer 52.

The optical path length of waveguide 24 from output end 32c of multiplexer 32 to directional coupler 25 is equal to the optical path length of waveguide 26 from output end 32d to directional coupler 27. The optical path length of waveguide 50 from directional coupler 51 to input end 52a is equal to the optical path length of waveguide 50 from directional coupler 51 to input end 52b. The phase of light is hardly shifted.

By suppressing the influence of the splitting ratio deviation and suppressing the phase deviation, in principle, the transmitted light is canceled out and does not propagate to waveguide 56 as in the example of FIG. 9. The reflection light is canceled out and does not propagate to waveguide 22. The same applies to the example of FIG. 10. Crosstalk is suppressed and the two resonance modes are excited independently. Transmitted light T4 and transmitted light T5 can be separated and extracted. Reflection light R4 and reflection light R5 can be separated and extracted. These lights can be used for different purposes.

As illustrated in FIG. 2, the waveguide and ring resonator 34 are formed of waveguide core 14 of Si. Light is confined in the curved waveguide, and loss can be suppressed. Even when the bending radius of ring resonator 34 is reduced, the loss of light can be suppressed. The circumferential length is shortened, and the FSR can be increased.

### Third Embodiment

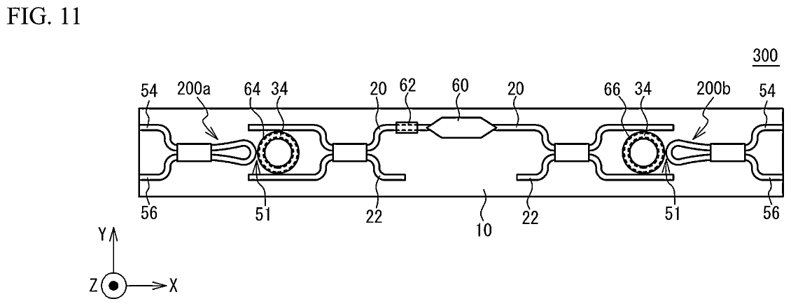

FIG. 11 is a plan view illustrating a wavelength tunable laser element 300 according to the third embodiment. The description of the same configuration as that of the first embodiment or the second embodiment will be omitted.

Wavelength tunable laser element 300 is formed on substrate 10 and includes a light source 60 and two optical filters 200. Optical filter 200 has the configuration of the second embodiment. One of two optical filters 200 is referred to as an optical filter 200a, and the other is referred to as an optical filter 200b. Optical filter 200a and optical filter 200b share waveguide 20. The circumferential length of ring resonator 34 of optical filter 200a is different from the circumferential length of ring resonator 34 of optical filter 200b. Optical filter 200a and optical filter 200b form a laser resonator.

Wavelength tunable laser element 300 includes a heater 62, a heater 64, and a heater 66 (phase adjusting units). The heater is made of metal and is electrically connected to an external power supply or the like. Heater 62 is provided in waveguide 20. Heater 64 is provided in ring resonator 34 of optical filter 200a. Heater 66 is provided in ring resonator 34 of optical filter 200b. When the heater is energized, the heater generates heat, and the silicon waveguide is heated. As the temperature rises, the optical path length changes, and the phase of the light changes. The resonance wavelength is changed by the adjustment of the phase.

Light source 60 is, for example, a semiconductor light-emitting element, is formed of a III-V group compound semiconductor, and has an optical gain. Light source 60 is bonded to one surface of substrate 10, is positioned on waveguide 20, and is optically coupled to waveguide 20. When power is input to light source 60, light source 60 emits light. The light emitted from light source 60 is transferred to waveguide 20 and is incident on optical filter 200a and optical filter 200b.

When light is incident from light source 60, optical filter 200a and optical filter 200b generate reflection light and transmitted light. The reflection light of optical filter 200a propagates through waveguide 20 toward light source 60. The reflection light of optical filter 200b propagates through waveguide 20 toward light source 60. The light is repeatedly reflected between optical filter 200a and optical filter 200b.

Since the circumferential lengths of two ring resonators 34 are different from each other, the FSR of optical filter 200a is different from the FSR of optical filter 200b. Due to the Vernier effect, the light laser-oscillates at a wavelength at which two optical filters 200 show peaks. The laser light is emitted from waveguide 54 of optical filter 200a and optical filter 200b.

Light is also incident on waveguide 22 of optical filter 200a and waveguide 22 of optical filter 200b. When light is incident on waveguide 22, optical filter 200a and optical filter 200b generate reflection light and transmitted light. The transmitted light propagates through waveguide 56 of each optical filter and is emitted. By measuring the transmitted light of optical filter 200a, the characteristic of optical filter 200a can be monitored. By measuring the transmitted light of optical filter 200b, the characteristic of optical filter 200b can be monitored.

According to the third embodiment, optical filter 200a and optical filter 200b form a laser resonator. When light is incident on waveguide 20 from light source 60, the light is reflected by the two optical filters, and is laser-oscillated. The laser light is emitted from waveguide 54 of optical filter 200a and optical filter 200b. When light is incident on waveguides 22 of optical filter 200a and optical filter 200b, the light is emitted from waveguide 56. Optical filter 200a and optical filter 200b are monitored using the light emitted from waveguide 56 as the light for monitoring. The wavelengths of light are matched between optical filter 200a and optical filter 200b. The light is laser-oscillated at the wavelength. The oscillation wavelength can be controlled.

Since crosstalk is suppressed in optical filter 200a and optical filter 200b, the light for monitoring is less likely to be mixed with the laser light, and these lights can be separated from each other. It is possible to perform monitoring with high accuracy and output desired laser light.

The circumferential length of ring resonator 34 of optical filter 200a is different from the circumferential length of ring resonator 34 of optical filter 200b. The resonance wavelengths of the two optical filters are matched, and light is laser-oscillated at the matched wavelength.

A heater is used for controlling the wavelength. By energizing heater 62, heater 64, and heater 66, the phase of the light can be adjusted and the resonance wavelength can be changed. The number of heaters may be increased from the example of FIG. 11.

The coupling coefficient of directional coupler 51 of optical filter 200a may be different from the coupling coefficient of directional coupler 51 of optical filter 200b. The ratio of emitted light can be controlled.

Although the embodiments of the present disclosure have been described in detail, the present disclosure is not limited to the specific embodiments, and various modifications and changes can be made within the scope of the gist of the present disclosure described in the claims.

1. An optical filter comprising:
a first multiplexer having a first input end, a second input end, a first output end, and a second output end;
a first waveguide optically coupled to the first input end;
a second waveguide optically coupled to the second input end;
a third waveguide optically coupled to the first output end;
a fourth waveguide optically coupled to the second output end; and
a ring resonator optically coupled to the third waveguide and the fourth waveguide.

2. The optical filter according to claim 1, comprising:
a second multiplexer having a third input end, a fourth input end, a third output end, and a fourth output end;
a fifth waveguide optically coupled to the third output end; and
a sixth waveguide optically coupled to the fourth output end,
wherein the third waveguide is optically coupled to the third input end, and
wherein the fourth waveguide is optically coupled to the fourth input end.

3. The optical filter according to claim 2,
wherein an optical path length of the third waveguide from the first output end to a coupling portion in which the third waveguide and the ring resonator are coupled to each other is equal to an optical path length of the fourth waveguide from the second output end to a coupling portion in which the fourth waveguide and the ring resonator are coupled to each other, and
wherein an optical path length of the third waveguide from the coupling portion in which the third waveguide and the ring resonator are coupled to each other to the third input end is equal to an optical path length of the fourth waveguide from the coupling portion in which the fourth waveguide and the ring resonator are coupled to each other to the fourth input end.

4. The optical filter according to claim 2,
wherein the ring resonator, the first waveguide, the second waveguide, the third waveguide, the fourth waveguide, the fifth waveguide, and the sixth waveguide are each made of silicon.

5. The optical filter according to claim 1, comprising:
a third multiplexer having a fifth input end, a sixth input end, a fifth output end, and a sixth output end;
a seventh waveguide optically coupled to the fifth input end, the ring resonator, and the sixth input end;
an eighth waveguide optically coupled to the fifth output end; and
a ninth waveguide optically coupled to the sixth output end.

6. The optical filter according to claim 5,
wherein a first end portion of the seventh waveguide is optically coupled to the fifth input end, and a second end portion of the seventh waveguide is optically coupled to the sixth input end, and
wherein the seventh waveguide is coupled to the ring resonator between the first end portion and the second end portion.

7. The optical filter according to claim 5,
wherein an optical path length of the third waveguide from the first output end to a coupling portion in which the third waveguide and the ring resonator are coupled to each other is equal to an optical path length of the fourth waveguide from the second output end to a coupling portion in which the fourth waveguide and the ring resonator are coupled to each other, and
wherein an optical path length of the seventh waveguide from a coupling portion in which the ring resonator and the seventh waveguide are coupled to each other to the fifth input end is equal to an optical path length of the seventh waveguide from the coupling portion in which the ring resonator and the seventh waveguide are coupled to each other to the sixth input end.

8. The optical filter according to claim 5,
wherein the ring resonator, the first waveguide, the second waveguide, the third waveguide, the fourth waveguide, the seventh waveguide, the eighth waveguide, and the ninth waveguide are each made of silicon.

9. A wavelength tunable laser element comprising:
a light source; and
two optical filters,
wherein each of the two optical filters includes
a first multiplexer having a first input end, a second input end, a first output end, and a second output end,
a first waveguide optically coupled to the first input end,
a second waveguide optically coupled to the second input end,
a third waveguide optically coupled to the first output end,
a fourth waveguide optically coupled to the second output end,
a ring resonator optically coupled to the third waveguide and the fourth waveguide,
a third multiplexer having a fifth input end, a sixth input end, a fifth output end, and a sixth output end,
a seventh waveguide optically coupled to the fifth input end, the ring resonator, and the sixth input end,
an eighth waveguide optically coupled to the fifth output end, and
a ninth waveguide optically coupled to the sixth output end,
wherein the light source is optically coupled to the first waveguides of the two optical filters.

10. The wavelength tunable laser element according to claim 9,
wherein circumferential lengths of the ring resonators of the two optical filters are different from each other.

11. The wavelength tunable laser element according to claim 9, comprising:
phase adjusting units each included in a corresponding one of the two optical filters and each configured to adjust a phase of light propagating through the corresponding optical filter.
